(19) United States
(12) Patent Application Publication
(10) Pub. No.: US 2018/0366620 A1
(43) Pub. Date: Dec. 20, 2018

(54) LIGHTING INTERLAYERS FOR OPTICAL PATHS OF LIGHT EMITTING OR ABSORBING SYSTEMS

(71) Applicant: OZYEGIN UNIVERSITESI, Istanbul (TR)

(72) Inventors: Mehmet ARIK, Istanbul (TR); Sedat NIZAMOGLU, Istanbul (TR)

(21) Appl. No.: 16/060,259

(22) PCT Filed: Dec. 20, 2016
(86) PCT No.: PCT/TR2016/050517

§ 371 Date: Jun. 7, 2018

(30) Foreign Application Priority Data
Dec. 22, 2015 (TR) 2015/16627

(51) Int. Cl. H01L 33/50; H01L 31/0232; H01L 31/0216; H01L 33/58; H01L 33/56

(52) U.S. Cl. CPC H01L 33/501; H01L 31/0232; H01L 31/0216; H01L 2933/005; H01L 33/56; H01L 2933/0041; H01L 33/58

(57) ABSTRACT

A light emitting or absorbing lighting system includes at least one radiation layer which is placed along the optical path of light with or without phosphor, makes radiation by absorbing light and contains silk fibroin, and which is capable of controlling the light distribution.

### TECHNICAL FIELD

Present invention is related to parts of systems emitting or absorbing light (for example, LEDs) which contain transparent (light transmitting) materials.

Present invention is especially related to lighting interlayers and lens materials which enhance the light-transmitting capacity of LEDs, and are resistant to heating, and are recyclable in nature.

### BACKGROUND OF THE INVENTION

Various different coating constructs or lens based systems are used with a view to enhancing the luminous efficacy of LEDs. Said coating constructs are commonly epoxy materials.

LEDs (light emitting diodes) used in the lighting field are preferred due to their various advantages such as long operating time, efficiency and color quality. LED technologies have in the recent times shown a rapid growth. Initially used as an indicator lamp in electronic devices, LEDs have attained a broad area of use thanks to new properties added thereto in the recent years. At the present time, they are being commonly used in many different areas in need of light from indoor lighting applications to street lamps, from automobile lighting systems to electronic devices. An application titled “Light Emitting Diode Fabrication Method”, application no. U.S. 2015111328, focused on LED manufacturing may be given as an example thereto. LED lighting technology uses LED chips and packages as a light source. Their internal structure is comprised of a light forming chip with electrical connection, and a clear transparent coating (encapsulant) on chip containing a fluorescent luminescent material absorbing electroluminescence occurring on chip, and a transparent outer container spreading a light of desired values around. Clear transparent materials are generally made of epoxy silicon material. Epoxy and silicon materials available in optical paths of LEDs commonly used in TV, imaging systems and general lighting purposes today are of low thermal performance. Polymer silicon encapsulant is used as epoxy coating material. However, the period of decomposition in nature and the effects on nature of these synthetic materials are not fully and exactly known yet. Furthermore, thermal performance of these materials is very low. Their overall thermal characteristic is k<0.2 W/m-K. Studies are being conducted on various different materials in order to reduce disadvantages of synthetic materials used as stated above. Silk fibroin proteins are also one of these materials studied thereinfor. There are various different studies focused on obtaining a silk based biomaterial and on its areas of application.

This type of a study is disclosed in the application titled “Optically Transparent Silk Hydrogels”, no. WO2015048527. That application deals with luminous transmittance of silk hydrogel. Another application is presented under the title of “Spider Silk Protein Film, And Method For Producing Same” with application no. WO2014103799. That application deals with a film production method, and luminous transmittance of that film in films obtained from spider silks. Another application is titled “Sparingly water-soluble transparent silk fibroin film and preparation method thereof” and is numbered CN101967282. That application describes a method used for obtaining a water-soluble translucent film from silk fibroins. Another example in connection therewith is a patent application titled “Silk Electronic Components”, no. “WO2011130335”. That application mentions about a protein obtained from silk fibroin and its areas of use in electronic devices.

Tufts University and Tufts Technology Transfer Office (U.S.A.) have so far conducted various studies on silk based biomaterials. It is understood from Tufts publications that they have performed studies with film and sponge formats of silk proteins on electronic elements, optical fiber elements, nanotechnology, micro fluids, lenses, medical products, glues, connection elements and similar other relevant fields. A summary of Tufts Technology Transfer Office has been published under the heading of “Tufts Silk Portfolio” (http://techtransfer.tufts.edu/tufts-silk-portfolio/). As another example, an article relating to application of silk fibroins in electronic equipments has been published under the heading of “Smooth as Silk “Transient Electronics” Dissolve in Body or Environment” on Sep. 27, 2012 (http://now.tufts.edu/news-releases/smooth-silk-transient-electronics). One of the relevant studies conducted by David Kaplan from Tufts University has been published under the heading of “The David Kaplan Lab” (http://sackler.tufts.edu/Faculty-and-Research/Faculty-Research-Pages/David-Kaplan). An article, attributed to David Kaplan and Fiorenzo Omenetto, and published under the heading of “The Light Fantastic” on Oct. 11, 2008, dealt with transparent silk film layers and with their use in optical field (http://www.tufts.edu/home/feature/?p=optics). In the article, it is stated that silk may be processed with water at room temperature through natural ways, and ecological products are obtained, and they are fit to body, and they can be used also in optical field. It is also stated that boiling and casting processes are performed for obtaining an optical material from silk, and it is then dried and crystallized, and that it has a wavelength between 400 and 700 nanometers in visible light.

The optical solution examples cited in the preceding paragraphs give information about obtaining optical products as a result of studies on silk based biomaterials and silk fibroins and about use of silk fibroins in optical field. The descriptions do not contain any detailed information on use of silk biomaterials in LEDS in the lighting area, and on any solutions or production methods in connection therewith. Nor do the publications given as an example hereinabove contain any way of solution where silk based biomaterials are specifically processed in the lighting area and are transformed into such a product form as a layer, film, capsule or coating. A transparent layer enhancing the illuminating capacity of LEDs has been developed in order to eliminate and overcome said disadvantages.

### BRIEF DESCRIPTION OF THE INVENTION

Present invention, departing from the state of the art, aims to eliminate the existing disadvantages thanks to improvements made in transparent illuminating parts of LEDs. Another purpose of present invention is to enhance illuminating capacity of LEDs. Yet another purpose of present invention is to keep the heating occurring in LED during illumination below the average heating values. And yet another purpose of present invention is to obtain a non-synthetic lighting interlayer that is recyclable in nature.

In order to achieve its purposes listed in the preceding paragraph, present invention provides a light emitting or absorbing lighting systems comprising at least one radiation layer which is placed along the optical path of light with or without phosphor, and makes radiation by absorbing light and contains silk fibroin, and which is capable of controlling the light distribution.

In a preferred embodiment of present invention, the aforementioned radiation layer contains transparent protein of wavelengths corresponding to various different colors in the visible region.

In another preferred embodiment of present invention, the aforementioned radiation layer contains transparent and biocompatible silk fibroin that may be eliminated by microorganisms in nature. This property may further make it possible for the life of coating to be proportionate to operating life of lamp. Furthermore, thanks to being biocompatible with microorganisms, the system used as a lamp may also be used as a sensor. As this lamp will also have the capability of communication and information transfer such as Li-Fi (Light Fidelity), it will also be possible to sense the quantity and form of microorganisms in environment, and to transmit this information to humans or machines.

In another preferred embodiment of present invention, the aforementioned radiation layer contains transparent protein of wavelengths corresponding to a single color in the visible region.

In another preferred embodiment of present invention, the aforementioned radiation layer contains transparent and biocompatible silk fibroin that may be eliminated by microorganisms in nature.

In another preferred embodiment of present invention, the aforementioned radiation layer contains at least one material such as phosphor, nanocrystals, e.g. quantum dots, and dyes, for the sake of assuring that it makes radiation in the desired light color and quality.

In another preferred embodiment of present invention, the said lighting system is a LED package.

In another preferred embodiment of present invention, the aforementioned radiation layer is directly placed on a chip.

In another preferred embodiment of present invention, the aforementioned radiation layer is placed over a chip in the form of lens.

In another preferred embodiment of present invention, the said lighting system contains at least one epoxy sheath containing silk fibroin and making radiation by absorbing light produced by chip.

In another preferred embodiment of present invention, the aforementioned radiation layer is placed between chip and epoxy sheath surface in such manner to cover at least a part of optical path of LED package.

In another preferred embodiment of present invention, the aforementioned radiation layer is placed at a particular distance from chip in such manner to cover at least a part of optical path of LED package.

Present invention is described in more details by the description given in the example model shown in simplified from in the figures attached hereto.

### DESCRIPTION OF THE FIGURES

FIG. 1: A perspective view of components of a LED package in a representative application of present invention.

FIG. 2: Shows a light layer in capsule form containing chemicals, e.g. a mixture of phosphor which paves the way for change of color of light by silk fibroin.

FIG. 3: Shows a light layer in plate form containing silk fibroin.

FIG. 4: Shows a light layer in lens form containing silk fibroin.

### DETAILED DESCRIPTION OF THE INVENTION

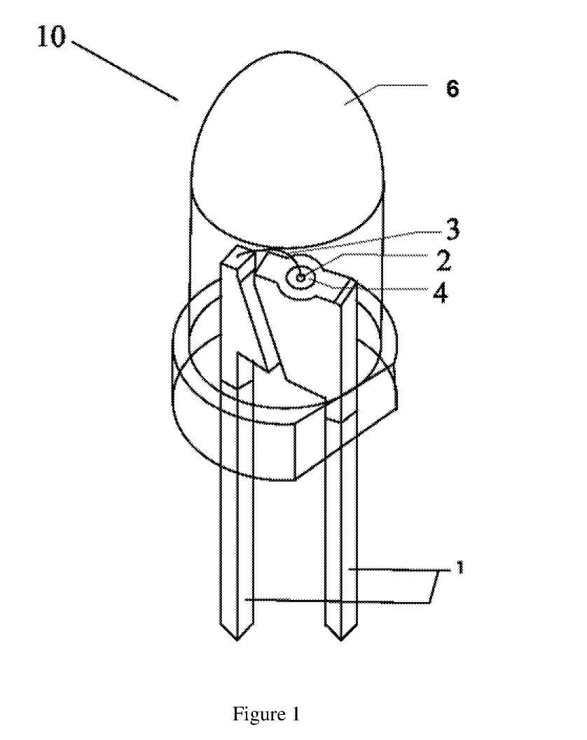

Application of present invention shown in FIG. 1 is a LED package illuminating device. Basic elements constituting LED package (10) are as follows: LED packages (10) are generally comprised of electrical contacts (1) being the connection point of external electrical power sources, and a chip (2) making electroradiation by using the current coming from electrical contacts (1), and a connective wire (3) ensuring passage of current from electrical contacts (1) to chip (2), and a cavity (4) in which chip (2) is located, and a transparent epoxy sheath (6) assuring spread of radiation occurring in chip (2) around. Electrical contact (1) is the connection point of external electrical power source. Current driving the LED is transmitted from the first main power source to this point. Chip (2) is termed and named as LED chip. Said chip makes electroradiation by using the incoming current. Current in electrical contacts is carried to chip (2) through connective wire (3). Epoxy sheath (6) is a type of epoxy container which both functions as a lens, thereby adjusting the appearance of emerging light, and provides protection thereof against external physical factors.

The development, being the subject of present invention, is related to transparent material parts of LED packages (10). Thanks to a light-emitting radiation layer (5) containing a material which is coated on chip (2) and makes radiation by absorbing electroradiation produced by chip (2), the illuminating capacity is enhanced, and resistant is provided against heating, and material is made recyclable in nature. Transparent material part is generally epoxy sheath (6).

Present invention is primarily based on use of silk fibroin material in radiation layer (5) and epoxy sheath (6) parts placed along optical exit path (A) of light. With reference to FIG. 1, present invention is provided by a radiation layer (5) containing silk fibroin, which is placed around chip (2) and makes radiation by absorbing electroradiation produced by chip (2). Present invention is further provided by an epoxy sheath (6) containing silk fibroin, which is coated on chip (2) and makes radiation by absorbing electroradiation produced by chip (2). Radiation layer (5) and epoxy sheath (6) layer, both containing silk fibroin, are layers with a high luminous transmittance, resistant against heating and recyclable in nature. Epoxy sheath (6) given in FIG. 1 is one of the most commonly used materials in a LED package (10). Therefore, it is fairly important to make this part reconciled with nature. Epoxy sheath (6) also contains biocompatible silk fibroin which makes radiation by absorbing electroradiation produced by chip (2). Silk fibroin is preferably biocompatible silk fibroin protein.

Silk fibroin is preferably made of transparent and biocompatible silk fibroin protein which may be eliminated by microorganisms in nature. The most important characteristic of silk fibroin protein contained in radiation layer (5) is that it transmits light and does not conduct heat. It is in the form of a transparent layer on the said chip (2).

Under normal conditions, heating in illuminating devices reduces the efficiency of circuit structure. Thanks to silk fibroin contained therein, radiation layer (5) is a coating material enhancing thermal characteristics. Silk fibroin is measured thermally and optically, and it is proven that its aforesaid characteristics are more superior than the existing materials. Heat conduction is 10 times more, and this property enhances the life of the illuminating device. Thus, a resistance which is 10 times less than that of the existing technologies occurs, and local heating is minimized or totally eliminated. Furthermore, it is proven and demonstrated by tests that it will increase thermal performance of illuminating materials and will be higher than k>4 W-m-K. This will in turn eliminate the local hot points in LEDs. Hence, a problem which plays a very important role in LED technology will have been resolved.

Environmental damages of LEDs having a radiation layer (5) containing silk fibroin are lower if and when compared to the existing LEDs of the state of the art.

Raw material of silk fibroin is cocoon. Hence, the sources of procurement of its raw material are high. Radiation layer (5) is cured on chip (2) by dripping method. Its curability in room temperature without any need of heating is another advantage provided by it. By use of radiation layer (5) containing silk fibroin, LED packaging (10) becomes more effective and efficient. Thus, a very important portion up to >20% of the optically lost light may be recovered.

As silk fibroin is optically transparent, in radiation layer (5), a material radiating into silk fibroin at the desired wavelengths may be used. Silk fibroin layer is transparent protein at wavelengths corresponding to various different colors in the visible region. Silk fibroin layer may also be transparent protein at wavelengths corresponding to a single color in the visible region. In an alternative application, radiation layer (5) may contain materials making radiation at a wavelength corresponding to a single color (radiating in a narrow range if compared to wide radiating materials such as phosphor) in the visible region. For radiation layer (5), all kinds of fluorescent luminescent materials or combinations of materials such as phosphor, nanocrystals, e.g. quantum dots, and dyes may be used. Thus, a LED package which can radiate at the desired light color and quality, and color rendering index (CRI), correlated color temperature (CCT), lumen level, etc. parameters of which may be adjusted as desired is obtained.

In an embodiment of present invention, radiation layer (5) contains phosphor together with silk fibroin. In another embodiment of present invention, radiation layer (5) contains phosphor and quantum dots together with silk fibroin. In any case, it is possible to obtain different light colors by changing and adjusting the ratio of materials in radiation layer (5).

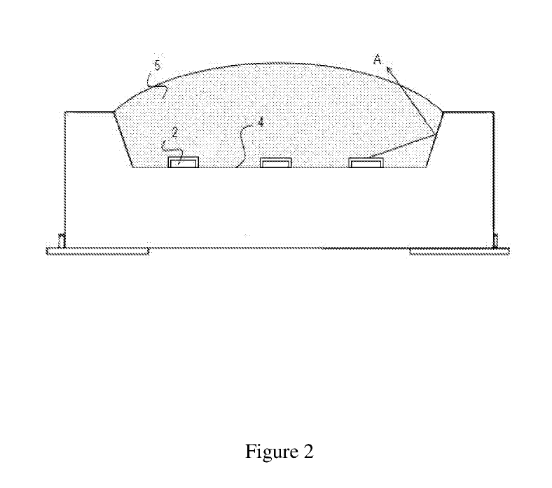

With reference to FIG. 2, in an embodiment of present invention, radiation layer (5) is structured in the form of a capsule. Said LED package contains more than one chip (2). Radiation layer (5) is placed and structured along optical path (A) of LED package (10), in such manner to cover at least a part of said optical path (A). Thus, radiation layer (5) is placed between epoxy sheath (6) surface and chip (2). In radiation layer (5), the silk fibroin and phosphor mixture is preferably situated in a built-in manner known as “settled” in the literature. In another preferred embodiment of present invention, in radiation layer (5), the mixture of silk fibroin and fluorescent luminescent phosphor, quantum dots, organic dye, etc. is settled on chip in the form of a lens and in such manner like a dome. Optionally, a protector may be used on chip (2). Chip may be made of protective silicon material.

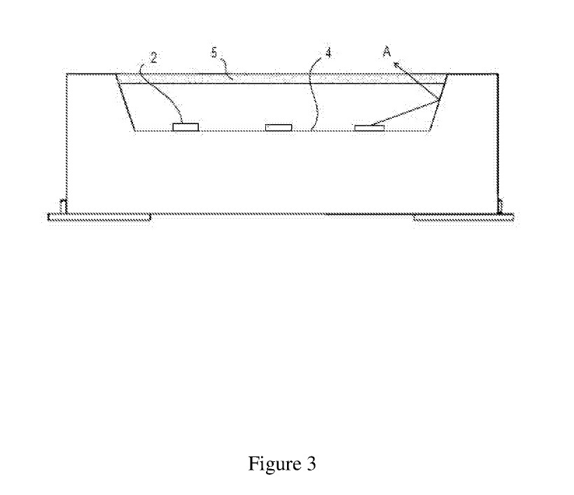

With reference to FIG. 3, in another embodiment of present invention, radiation layer (5) may also be employed as a permeable plate in front of translucent system. Radiation layer (5) is placed and structured along optical path (A) of LED package (10), in such manner to cover at least a part of said optical path (A).

Thus, radiation layer (5) is structured in the form of a plate at a certain distance from chip (2), underneath epoxy sheath (6). In this type of structure, a biocompatible silk fibroin protein is available in radiation layer (5) functioning as a permeable plate in front of light-transmitting hardware of LED package (10). A more environmentalist illumination is provided by means of biocompatible silk fibroin protein.

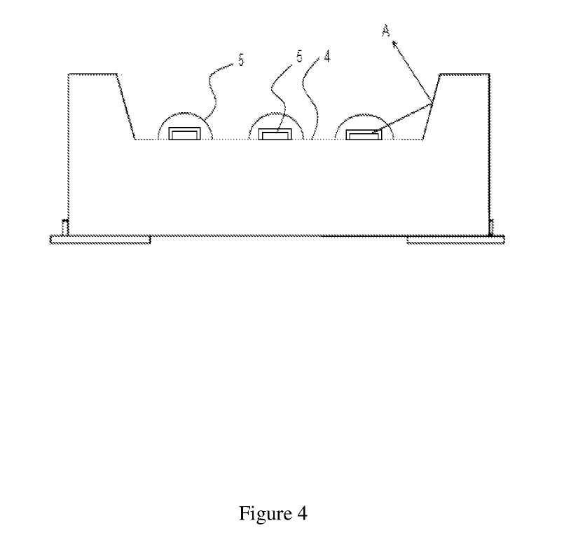

With reference to FIG. 4, in another embodiment of present invention, radiation layer (5) containing silk fibroin may be used in the form of a lens on LED. Furthermore, in another embodiment of present invention, radiation layer (5) may be directly placed on chip (2). In this embodiment, The surface of chip may have been appropriately processed. The chip may be coated by silk fibroin or specifically by a silk fibroin reactive layer, and be directly placed on PCB plate as a cap. Optionally, a protector may be used on chip (2). Chip may be made of protective silicon material.

In an exemplary implementation of LED package (10), first of all, the current formed as a result of electrical voltage generated by an external electrical power source passes through electrical contacts (1) and via the wire (3) combining LED and contacts, and drives the chip (2). Chip (2) makes electroradiation by using the incoming current. Radiation layer (5) containing silk fibroin absorbs electroradiation produced by chip (2), and makes fluorescent luminescence. Electroradiation and fluorescent luminescence are combined, and exit from epoxy sheath (6) containing a biocompatible silk fibroin protein making radiation by absorbing electroradiation, and spread over to the targeted outer atmosphere.

Basic scope of present invention as described in claims will be evaluated without keeping present invention limited by the representative applications specified herein. Thus, alternative structures which may be implemented by persons skilled in the art on the basis of basic and fundamental elements included in the scope of protection described in claims will be treated and considered as an infringement on present invention.

### REFERENCE SIGNS

10 Led package
1 Electrical contact
2 Chip
3 Connective wire
4 Cavity
5 Radiation layer
6 Epoxy sheath
A Optical path

1. A light emitting or absorbing lighting system, having an electroluminescent chip and an epoxy sheath that causes the radiation to be emitted, characterized in that it comprises at least one radiation layer absorbing light along the optical path of light with or without phosphor between said chip and said epoxy sheath and making radiation by controlling the light distribution, containing silk fibroin.

2. Light emitting or absorbing lighting system according to claim 1, characterized in that the said radiation layer contains materials making radiation of wavelengths corresponding to various different colors in the visible region.

3. Light emitting or absorbing lighting system according to claim 1, characterized in that the said radiation layer contains transparent and biocompatible silk fibroin that may be eliminated by microorganisms in nature.

4. Light emitting or absorbing lighting system according to claim 1, characterized in that the said radiation layer contains materials making radiation of wavelengths corresponding to a single color in the visible region.

5. (canceled)

6. Light emitting or absorbing lighting system according to claim 1, characterized in that the said radiation layer contains at least one material making radiation such as phosphor, nanocrystals, e.g. quantum dots, and dyes, for the sake of assuring that it makes radiation in the desired light color and quality.

7. Light emitting or absorbing lighting system according to claim 1, characterized in that it is a LED package.

8. (canceled)

9. Light emitting or absorbing lighting system according to claim 1, characterized in that the radiation layer is in the form of a lens placed on said chip.

10. (canceled)

11. Light emitting or absorbing lighting system according to claim 1, characterized in that said epoxy sheath contains silk fibroin.

12. (canceled)

13. (canceled)

14. Use of a lighting system in accordance with claim 1 as a sensor compatible with microorganisms in environment in the form of a biocompatible coating or a lens.

15. Use according to claim 13, characterized in that said lighting system measures on real time basis the luminous transmittance and lens thickness, as well as quantity and form of microorganisms, and transfers such information via Li-Fi communication system to humans and machines available therein.

16. A lighting system according to claim 1, characterized in that the radiation layer, chip and chips are in capsule form along a specified distance.

17. A lighting system according to claim 1, characterized in that the radiation layer, chip and chips are in lens form along a specified distance.

18. A lighting system according to claim 1, characterized in that the radiation layer, chip and chips are in plate or film form along a specified distance.

19. A lighting system according to claim 1, characterized in that the radiation layer is in form of a layer or a cover directly on the chip or on a protective layer applied onto the chip.

20. A method of production of a radiation layer absorbing light in LED package and making radiation by controlling the distribution of light, containing silk fibroin, characterized in that it comprises the step of curing the silk fibroin at room temperature by dropping on the chip.
